(19) United States
(12) Patent Application Publication
(10) Pub. No.: US 2016/0377981 A1
(43) Pub. Date: Dec. 29, 2016

(54) SELECTIVE LASER ABLATION IN RESISTS AND BLOCK COPOLYMERS FOR HIGH RESOLUTION LITHOGRAPHIC PATTERNING

(71) Applicants: Deirdre L. Olynick, El Cerrito, CA (US); Adam Schwartzberg, Walnut Creek, CA (US)

(72) Inventors: Deirdre L. Olynick, El Cerrito, CA (US); Adam Schwartzberg, Walnut Creek, CA (US)

(73) Assignee: The Regents of the University of California, Oakland, CA (US)

(21) Appl. No.: 15/160,097

(22) Filed: May 20, 2016

Related U.S. Application Data
(60) Provisional application No. 62/164,823, filed on May 21, 2015.

(51) Int. Cl. G03F 7/039; B23K 26/402; B23K 26/364

(52) U.S. Cl. CPC G03F 7/039; B23K 26/364; B23K 26/402

(57) ABSTRACT

Various embodiments of the invention demonstrate selective laser ablation processes as a means to create a block copolymer derived lithographic pattern through the selective removal of one block. Three block copolymer systems described PS-b-PHOST, P2VP-b-PS-b-P2VP, and P2VP-b-PS-b-P2VP where the P2VP is infiltrated with platinum Pt. The selective laser ablation processes on block copolymers offers an alternative to plasma etching when plasma etching is not effective.

### CROSS REFERENCE TO RELATED APPLICATIONS

This U.S. Utility Application claims priority to U.S. Provisional Application Ser. No. 62/164,823 filed May 21, 2015, which application is incorporated herein by reference as if fully set forth in their entirety.

### STATEMENT OF GOVERNMENTAL SUPPORT

The invention described and claimed herein was made in part utilizing funds supplied by the U.S. Department of Energy under Contract No. DE-ACO2-05CH11231 between the U.S. Department of Energy and the Regents of the University of California for the management and operation of the Lawrence Berkeley National Laboratory. The government has certain rights in this invention.

### BACKGROUND OF THE INVENTION

### Field of the Invention

Block copolymer lithography (BCPL) offers an appealing option for patterning structures at the 3-30 nm size scale. Industrial applications for semiconductor chip manufacturing and hard drives are on the horizon, but as noted in a recent review by Bates, et. al. will require overcoming challenges in many areas, including pattern transfer. As noted in the review by Gu, et. al., there are two critical steps in BCPL pattern transfer, selective removal of one block and then transferring the pattern left by the remaining block to the substrate. In this paper we focus on the first step, selective block removal.

Plasma based dry etching (i.e. reactive-ion etching, RIE) is typically used for block removal over wet etching because it avoids pattern distortion/collapse caused by capillary forces in the wet block removal approach, as shown in the polystyrene-b-polymethylmethacrylate (PS-b-PMMA) system. However, not all block copolymer systems have selectivity in plasma-based chemistries and alternatives approaches need to be developed.

### BRIEF DESCRIPTION OF THE DRAWINGS

FIG. 1 illustrates laser ablation for protected and deprotected poly((t-butoxycarbonyloxy)styrene (BOCS).

FIGS. 2A, 2B, 2C and 2D illustrate images of selectively ablated PHOST from a PS-b-PHOST 46 nm in pitch. FIGS. 2A illustrates an AFM image. FIGS. 2B illustrates an AFM line scan of FIGS. 2A. FIGS. 2B illustrates an SEM image. Scale bar is 200 nm. FIGS. 2D illustrates an SEM overview of an ablated area, the lighter area is where ablation occurs.

FIG. 3 illustrates AFM images of P2VP-b-PS-b-P2VP with a 20 nm pitch.

FIG. 4 illustrates a SEM image of ablated 10 nm half-pitch PS-b-PVP complexed with platinum.

### DETAILED DESCRIPTION

In the discussions that follow, various process steps may or may not be described using certain types of manufacturing equipment, along with certain process parameters. It is to be appreciated that other types of equipment can be used, with different process parameters employed, and that some of the steps may be performed in other manufacturing equipment without departing from the scope of this invention. Furthermore, different process parameters or manufacturing equipment could be substituted for those described herein without departing from the scope of the invention.

Various embodiments of the invention describe the selective laser ablation process for block copolymer lithography (BCPL) in three systems where there is difficulty using traditional reactive ion etch (RIE) to remove one block selectively, specifically : polystyrene-b-polyhydroxyl-styrene (PS-b-PHOST), poly-2-vinylpyridine-b-polystyrene-b-poly-2-vinylpyridine (P2VP-b-PS-b-P2VP), and P2VP-b-PS-b-P2VP where the P2VP is infiltrated with platinum. For neat BCPs, even if, e.g., they are microphase separated, the aromatic nature of the monomers makes the plasma etching rates similar. Two alternative methods have emerged to increase etch selectivity between blocks. One method includes selective infiltration synthesis, where one of the block copolymer domains is complexed with a metal organic prior to etching. The other method includes complexing one of the domains with a metal via a solution process which not only can improve the etching resistance, but also can increase the ability to microphase separate the smaller domains. Laser ablation may be able to replace or complement these techniques. For instance, in PS-b-P2VP, where the PVP (P2VP) is complexed with a metal to increase the etching resistance, the metal can phase segregate during etching, degrading the pattern transfer. In contrast, laser ablation has proven to be gentler process for block removal.

As discussed in reviews by Lippert, laser-ablation has been used to pattern polymers down to the diffraction limit of the scanning laser since 1982. Typically the laser is in the UV range where the absorption of most polymers is high. More recently, a few authors have applied laser ablation to selectively remove blocks in block-copolymers. In this case, the resolution of the pattern is not determined by the size of the laser beam or the masking pattern, but instead by the chemical pattern in the polymer. Ahn, et. al. used an eximer laser and removed the one block that was more UV-sensitive so that, after the ablation, polystyrene dots remained. Overall, however, the final PS structure was thinner than the original. Wang, et. al. doped the PVP block of a PS-b-P4VP block copolymer to induce visible light laser ablation at 532 nm.

In various embodiments described, we build upon our previous success in selective laser ablation for dry development of a high-resolution resist material, methyl acetoxy calixarene. In our selective ablation process, we expose the calixarene using electron beam lithography and replace the wet development step with laser ablation. We found there is a difference in absorption between the exposed and unexposed regions allowing selective development of the exposed region. This selective ablation of the exposed area means the resolution is determined by the e-beam pattern, not by the laser spot size which is on the order of 300 nm FWHM. We were able to laser develop the e-beam exposed calixarene down to 15 nm half-pitch features in films thicknesses of 100 nm. The performance of the ablation was far better than that achieved by wet development. Wet development under identical electron beam exposure conditions caused pattern collapse in part due to capillary forces during drying and, possibly, feature swelling.

We studied the mechanism through systematic analysis of this and other chemical systems and found two components that contribute to the increase in 532 nm absorption, the increase of extended conjugation and the appearance of —OH groups on the aromatic ring due to electron beam induced chemistry. While not wishing to be bound by theory, we believe the aromatic-OH group can form a long-lived proton adduct, aromatic-OH₂⁺, when exposed to e-beam or lasers and this species has a 532 nm absorption. We also verified, that working at 532 nm had and advantage over CW ultraviolet laser in that there was much weaker absorption, due to a shoulder of a UV absorption in pristine, unexposed calixarene film. This means the thinning of the unexposed material can be minimized compared to the ultra-violet regime where both the exposed and unexposed film have significant absorption. Using the selective ablation mechanism in the studied calixarene system, we saw a clear opportunity to pattern block copolymers using visible wavelength lasers, especially in the PS-b-PHOST system. This system is believed to have a selectivity due to the presence of aromatic-OH's in the hydroxy styrene system.

In various embodiments, we extend selective laser ablation first to polyhydroxy styrene with and without t-butoxycarbonyl protecting groups to verify the mechanism for phenolic systems, and then we move to block copolymers. First, we demonstrated conditions for selective ablation in the PS-b-PHOST system. Finally, we extend our study to the PS-b-PVP system with and without platinum (Pt) complexed in the PVP. Again, not wishing to be bound by theory, we expect the mechanism for the platinum system to be different.

### EXPERIMENTAL

### Polymer Film Preparation:

Poly((t-butoxycarbonyl)oxy)styrene (BOCS) was diluted in ethyl lactate and spun coat to a thickness of 100 nm. Samples were baked one minute at 100° C. after spinning. Triphenylsulfonium triflate (TPSOTf) was added as a photo-acid generator to promote the deprotection of BOCS

PHOST-b-PS synthesis is described in Bates et al¹. Silicon substrates were coated with a neutral underlayer. The block copolymers solutions were made using PGMEA as a casting solvent and filtered through 0.2 um PTFE filters. BCP films were made by spin casting on neutral substrate. Spun films were baked at 120° C. for 2 min to remove the casting solvent resulting in 20 nm films as measured by ellipsometry (Woollam M-1000V). BCP films were solvent annealed in sealed containers with 0.15% volume acetone for 6 hours.

P2VP-b-PS-b-P2VP (47 k) was dissolved in Toluene/THF (3:1) mixed solvent to prepare 10 mg/mL solution, and was filtered with 0.45 μm PTFE syringe filters before coated onto P(S-r-2VP-r-HEMA) grafted silicon substrates, to prepare films with thickness of 28 nm. The BCP thin films were then annealed in acetone vapor environment in a sealed chamber for 1 hour. For platinum containing samples, Na₂PtCl₄ salt was infiltrated into the BCP thin film by immersing the annealed film into 20 mg/mL Na₂PtCl₄ aqueous solution with 0.9% HCl for 3 hours. Due to the polarity of P2VP domain, Na₂PtCl₄ salt and HCl acid was selectively infiltrated into the P2VP domain. The metal stained BCP films were then rinsed with deionized water and dried in vacuum.

Laser exposure and fluorescence studies: The laser exposures were performed in a Witec micro-Raman system (used also for the simultaneous Raman characterization) with a Nikon 100×/0.95 NA objective (˜300 nm diameter focus, 0.07 μm² area) and a 532 nm CW laser with a 30 mW maximum power. Power numbers quoted are after the lens which absorbed approximately 25% on the incident power. As the ablation onset is very sensitive to power density variations and hence focal depth, the laser was focused each time the sample stage was moved by maximizing the Raman signal from the underlying silicon substrate.

Large area electron beam exposures on T-BOC: For mechanistic studies, a large area (2×2 cm²) electron beam were produced using a Kimball Physics electron flood gun (EGG-3101, spot size 1 mm, 10 keV).

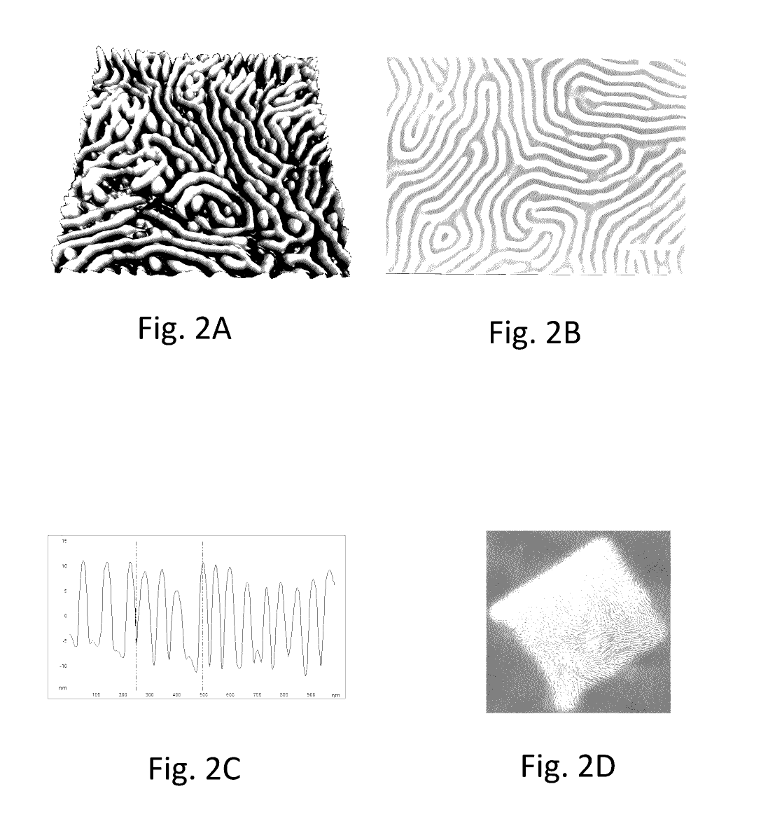

SEM and AFM imaging of ablation. Block copolymers before and after ablation were imaged in SEM using a Zeiss Ultra 100 at 2-3 keV beam voltages. For AFM, either a Bruker's Dimension Icon® AFM (FIG. 2) with high resolution cantilevers (tip radius 2-4 nm) or an Asylum MFP-3D Atomic Force Microscope with standard cantilevers in non-contact mode (“tapping mode”) were used. The setpoint was adjusted to be in the repulsive regime for enhanced topography and phase contrast.

### RESULTS

The ablation process in PHOST, the role of the aromatic-OH.

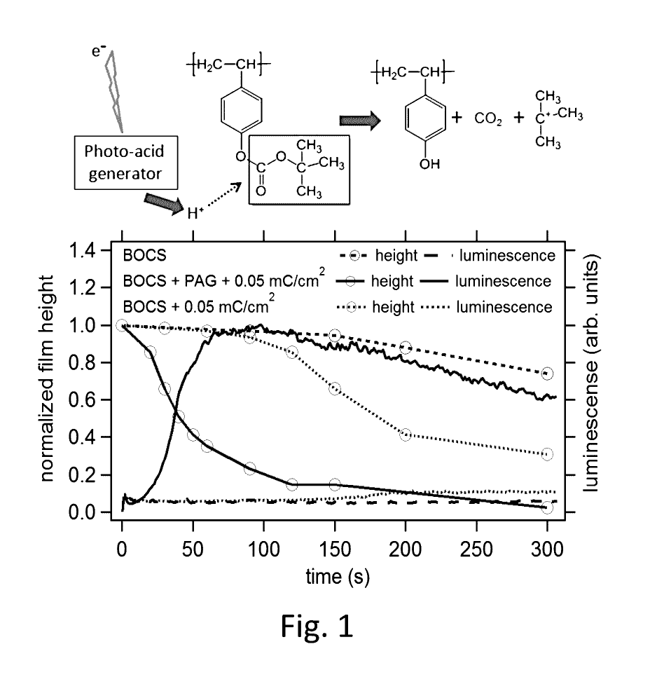

FIG. 1 illustrates laser ablation for protected and deprotected poly((tbutoxycarbonyloxy)styrene (BOCS). High levels of deprotection are achieved with the addition of a photo-acid generator (PAG). Below, luminescence together with the corresponding film thickness vs. time curves for BOCS with and without PAG. Prior to laser exposure 2 films were treated with flood electron beam at a dose of 0.5 mC/cm². Curves were measured upon irradiation with 3.7 mW, focused, 532 nm light.

The first step in the analysis was to confirm that aromatic-OH plays a role in the PHOST system analogous to the calixarenes. In FIG. 1, we compare ablation in the poly((tbutoxycarbonyloxy)styrene (BOCS), the protected PHOST system, to the deprotected system. Deprotection is accomplished by exposing to 0.05 mC/cm² of 10 keV electrons with and without 10% by weight of photo acid generator (PAG). The addition of PAG allows deprotection via the mechanism shown in FIG. 1.

The deprotected sample shows an immediate onset of photoluminescence, while no luminescence is observed from the BOCS protected material. Furthermore, only a weak photoluminescensce signal appeared in the e-beam exposed sample of pure BOCS after a significant laser exposure time Like in calixarenes, this luminescence is directly correlated to the ablation as shown by measurement of the film height as a function of laser exposure time. As expected, thickness measurements show that ablation starts immediately for the deprotected sample. Ablation is virtually absent the pristine BOC sample. The e-beam exposed BOCS, no PAG, shows partial ablation (70% of the film) but only after a significant incubation time (delay between laser exposure and the onset of ablation). The dramatically accelerated ablation for the deprotected sample confirms the important role played by the hydroxyl groups in the ablation. Repeating the measurements with polystyrene, at this laser power, a long incubation time and little evidence of photofluoresence was noted.

### Selective Ablation in PS-b-PHOST

FIGS. 2A, 2B, 2C and 2D illustrate images of selectively ablated PHOST from a PS-b-PHOST 46 nm in pitch. FIGS. 2A illustrates an AFM image. FIGS. 2B illustrates an AFM line scan of FIGS. 2A. FIGS. 2B illustrates an SEM image. Scale bar is 200 nm. FIGS. 2D illustrates an SEM overview of an ablated area. Lighter area is where ablation occurs.

FIGS. 2A, 2B, 2C, and 2D collectively illustrate the selective ablation process on PS-b-PHOST. The PHOST block is removed in the 46 nm pitch system using powers of 7.5 mW, dwell times of 2 seconds, and pixel size of 333 nm. Selective ablation could be achieved in 40 nm samples under similar conditions. However, smaller pitches could not be selectively ablated. AFM phase imaging showed contrast within one block suggesting incomplete phase separation at smaller pitches. In addition, we found that in ablations studies of the underlayer, a cross-linked mixture of PS, poly glycidyl methacrylate, and polyacetoxy styrene, did not ablate, at similar powers as those used to remove the PHOST block from the bcp. For pattern transfer, this would indicate that a descum would be necessary.

### Ablation in PS-b-PVP With and Without Platinum Complex

We investigated ablation in the PS-b-PVP system which was expected to occur via a different mechanism than PS-b-PHOST since there are no aromatic-OH groups present. Previous authors found PS had a lower ablation threshold than PVP.

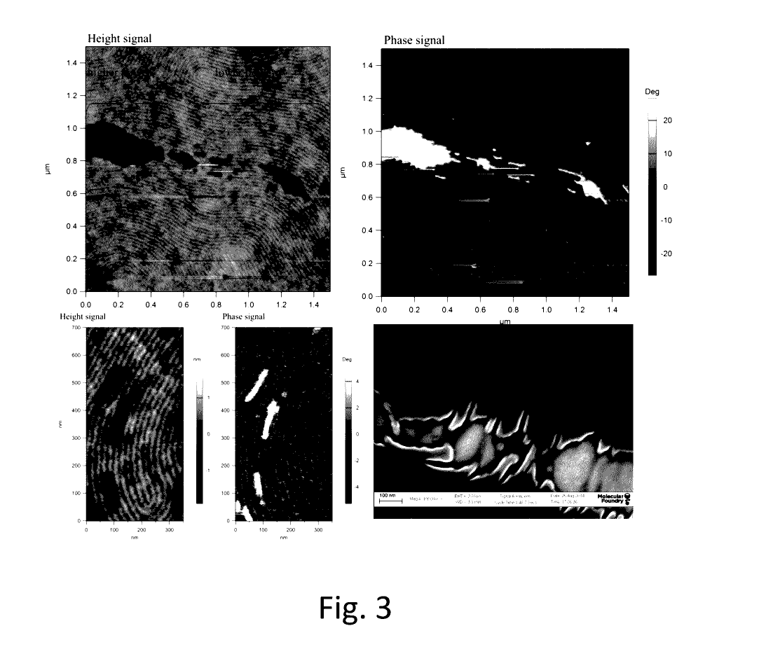

FIG. 3 illustrates AFM images of P2VP-b-PS-b-P2VP with a 20 nm pitch. Relatively high powers were needed to see any ablation (above 21 mW). The ablation was found to proceed with a preference to ablate along the block copolymer fingerprint pattern. As the dose was reduced at constant power, single blocks appeared to be removed but in an inconsistent fashion. Hence optimum conditions were not found for selective removal for the non-metal doped system.

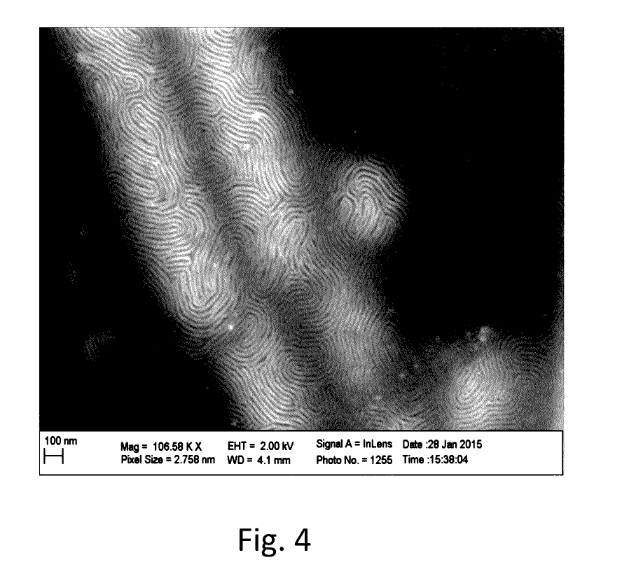

FIG. 4 illustrates a SEM of ablation in the PS-b-PVP system. The SEM image shows ablated 10 nm half-pitch PS-b-PVP complexed with Platinum. Scan lines are the overall light colored areas in the image. Contrast has changed and pattern collapse is apparent in parts of the image.

Powers were much lower than that used in the non-metal doped systems approximately between 10 mW and 15 mW (11.25 mW at the sample), yet the PS block is removed. It appears that the platinum addition may be playing two roles in the ablation process. On the one hand, it enhances the absorption and heat generation in the resist, leading to a photothermal degradation. On the other hand, it also promotes the stability of the PVP block. While RIE etching of the PS-PVP system caused the destabilization of the PVP blocks—the lines were found to be broken presumably due to agglomeration of the platinum as the organic is removed—we found no evidence of this in the laser ablation process. The ablation appears to be gentler on the PVP block while still allowing the PS to be selectively removed. It is believed that the metal salt acts as a radical quencher.

### CONCLUSIONS

Laser ablation to selectively remove one block in two types of block-copolymer systems is described. Using a 532 nm CW laser, we confirmed the mechanism that the selective ablation in e-beam patterned resists was consistent with studies in the PHOST system using protected and deprotected PHOST. Selective removal of PHOST is achieved in PS-b-PHOST and removal down to 20 nm half-pitch has been demonstrated. We then investigated P2VP-b-PS-b-P2VP, and P2VP-b-PS-b-P2VP doped with platinum. While poor selectivity was found in P2VP-b-PS-b-P2VP with no platinum, the P2VP-b-PS-b-P2VP platinum doped system allowed the selective removal of the PS block in the 10 nm half-pitch systems investigated. Described embodiments provide a viable path for patterning block copolymers where selectivity is not available with reactive ion etching.

### REFERENCES

[1] N. D. Jarnagin, J. Cheng, A. Peters, W.-M. Yeh, R. A. Lawson, L. M. Tolbert and C. L. Henderson, “Investigation of high &amp;chi; block copolymers for directed self-asssembly: synthesis and characterization of PS-b-PHOST,”Proc SPIE 8323, Alternative Lithographic Technologies IV 8323, 832310-832310-832319 (2012).

What we claim is:

1. A process for lithographic development comprising:
(i) depositing a layer of a resist material on a substrate, wherein the resist material comprises a block copolymer including a first block and a second block, wherein the second block further comprises a metal;
(ii) exposing the resist material to a light source, wherein a region of the resist material comprising the first block exposed to the light source is volatilized and removed and the second block comprising the metal remains.

2. The process of claim 1 wherein the light source is a laser light source.

3. The process of claim 2 wherein the laser light source is a 532 nm wavelength laser.

4. The process of claim 3 wherein the laser light source is operated at a power of between 10 mW and 15 mW.

5. The process of claim 1 wherein the metal comprises platinum (Pt).

6. The process of claim 1 wherein the metal comprises a metal salt.

7. The process of claim 6 wherein the metal salt comprises a sodium platinum chloride (Na₂PtCl₄) salt.

8. The process of claim 1 wherein the block copolymer comprises polystyrene-b-poly-2-vinylpyridine (PS-b-P2VP).

9. The process of claim 1 wherein the first block comprises polystyrene (PS).

10. The process of claim 1 wherein the second block comprises poly-2-vinylpyridine (P2VP).

11. The process of claim 1 wherein the block copolymer comprises poly-2-vinylpyridine-b-polystyrene-b-poly-2-vinylpyridine (P2VP-b-PS-b-P2VP).
